(19) United States
(12) Patent Application Publication
(10) Pub. No.: US 2025/0141448 A1
(43) Pub. Date: May 1, 2025

(54) IMPLEMENTATION OF LEAKAGE-TOLERANT LOGIC GATES

(71) Applicant: Neologic Ltd., Tel-Mond (IL)

(72) Inventor: Avi Messica, Tel-Mond (IL)

(73) Assignee: Neologic Ltd., Tel-Mond (IL)

(21) Appl. No.: 18/689,548

(22) PCT Filed: Sep. 8, 2022
(86) PCT No.: PCT/IL2022/050981

§ 371 Date: Mar. 6, 2024

Related U.S. Application Data
(60) Provisional application No. 63/243,223, filed on Sep. 13, 2021.

(51) Int. Cl. H03K 19/00

(52) U.S. Cl. CPC H03K 19/0013

(57) ABSTRACT

A logic gate circuit, comprising a logic block for performing logic operations between inputs of the logic block and a restoration block, connected between the output of the logic block and the output of the logic gate, for compensating for voltage level losses when the output being in a high logic state. The logic block discharges the voltage that corresponds to the high logic state to ground, following logic operations that entail a low logic state, via an inherent or a designed current leakage path in the components implementing the logic block.

### FIELD OF THE INVENTION

The present invention relates to the field of static logic gates. More particularly, the invention relates to a logic gate design that is based on a transistors stack with a reduced number of transistors in comparison to known CMOS and less semiconductor area.

### BACKGROUND OF THE INVENTION

Static Complementary Metal-Oxide-Semiconductor (CMOS) logic had evolved from N-type Metal-Oxide-Semiconductor (NMOS) logic to solve the excessive power dissipation issue of the latter by trading three-to-four times increase in area for improving power dissipation. Therefore, CMOS-logic gates are inferior in packing density to their single-type MOSFET counterparts, (e.g. NMOS logic). CMOS gates are also limited to a relatively small Fan-in (i.e., the number of inputs a gate can handle—in most cases up to four inputs).

Furthermore, advanced technology nodes suffer from high static power dissipation (due to subthreshold as well as junction leakage). As CMOS technology approaches 2 nm gate length, any further improvement in transistor gate-density (i.e., the number of transistors per unit area) via transistor shrinkage becomes challenging as the dimension of the transistor's gate approaches the size of roughly ten Si atoms.

U.S. Pat. No. 10,115,788 proposed further improved gate-density by packing transistors in a 3D structure of Gate-All-Around topology.

Another avenue is to reduce the number of transistors that are required for carrying out logic functions, thereby effectively improving gate density. This, however, requires devising a new topology of logic gates, i.e. different than conventional planar or FinFET CMOS-logic.

Many attempts were made to improve the performance of CMOS logic in terms of switching speed, power dissipation, and packing density. A popular alternative to CMOS-logic is static Pass-Transistor Logic (PTL) and Double Pass-transistor Logic (DPL) as described in U.S. Pat. Nos. 4,541,067 and 5,808,483, according to which NMOS transistors are used for realizing logic gates by having a set of control signals applied to the gates of NMOS transistors, and a set of data signals applied to the sources of the n-transistors.

Many PTL circuit implementations have been proposed in the literature (see for example W. AI-Assadi, A. P. Jaya Sumana, and Y. K. Malaiya, “Pass-transistor logic design”. International Journal of Electronics, 1991, Vol. 70, no. 4, pp. 739-749, R. Zimmermann, W. Fichtner, “Low-Power Logic Styles: CMOS Versus Pass-Transistor Logic”, IEEE Journal of Solid-State Circuits, vol. 32, no. 7, pp. 1079-1090, June 1997, and K. Bernstein, L. M. Carrig, C. M. Durham, and P. A. Hansen, “High-Speed CMOS Design Styles”, Kluwer Academic Press, 1998).

PTL advantages over known CMOS-logic are lower input capacitance, as well as higher gate density due to a lower transistors count per logic function. However, most PTL implementations suffer from a threshold voltage drop—across the pass transistors—that results in reduced drive current and degraded logic-signal voltage that significantly limits the number of sequential stages that can be used. Ratioed logic uses NMOS transistors of different channel widths connected with resistive load to achieve logic functionality and is similar to NMOS-logic. However, its disadvantages are sensitivity to process variations due to the need to maintain specific ratios between NMOS transistors of different channel widths as well as high static power dissipation.

Pseudo NMOS logic (PNL) was described by Rajeev Kumar and Vimal Kant Pandey “Low power combinational circuit based on Pseudo NMOS logic” in the International Journal of Enhanced Research in Science Technology & Engineering, Vol. 3 Issue 3, 2014, pp: (452-457) uses an NMOS-type pull-down network, like CMOS, in tandem with a gate-grounded PMOS transistor load or feedback connected PMOS load, as described in U.S. Pat. No. 5,467,026. Compared to CMOS-logic, it reduces the number of PMOS transistors but suffers from drawbacks similar to NMOS-logic; i.e. excessive dynamic and static power dissipation.

Techniques that attempt to solve the compromise in signal integrity of PTL (i.e., degraded voltage swing) are Transmission Gate logic (TGL) described in U.S. Pat. No. 5,200,907, as well as Complementary Pass-transistor Logic (CPL) described in U.S. Pat. No. 7,394,294. TGL combines a pair of PMOS and NMOS transistors placed in parallel to each other to realize complex logic functions using a small number of transistors. TGL solves the degraded voltage swing issue. However, it is more semiconductor area-consuming than known CMOS logic.

CPL features complimentary inputs-outputs using NMOS pass-transistor logic with CMOS output inverters. It uses series transistors to select between possible inverted output values of the logic, the output of which drives a standard CMOS inverter. However, CPL suffers from static power dissipation due to a low voltage that feeds the output inverter. Since complementary inputs are often required to control the CPL transistors, additional logic stages that increase area are required. U.S. Pat. No. 5,285,069 describes a method of multiple threshold voltages in a logic cell for reducing the distance between transistors to increase the packing density of a CMOS SRAM memory array.

Some of these design approaches contain either PMOS transistors or cross-coupled inverters for signal restoration to maintain full voltage swing. However, PTL often consumes a large area due to the use of PMOS transistors. An additional difficulty with PTL approaches is their design complexity. Unlike CMOS-logic, there is no standard cell library that is available for PTL. Furthermore, the fact that some input patterns to a PTL cell do not generate a full voltage swing output presents an obstacle for VLSI designers to use standard Electronic Design Automation (EDA) tools for PTL circuit design.

It is therefore an object of the present invention to provide a MOS logic gate design, which reduces power dissipation.

It is another object of the present invention to provide a MOS logic gate design, with reduced semiconductor area.

It is another object of the present invention to provide a MOS logic gate design, with a reduced number of P-MOS transistors.

Other objects and advantages of the invention will become apparent as the description proceeds.

### SUMMARY OF THE INVENTION

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions will control. In addition, the materials, methods, and examples are illustrative only and are not intended to be necessarily limiting.

A logic gate circuit, comprising:
a) a logic block for performing logic operations between inputs of the logic block; and
b) a restoration block, connected between the output of the logic block and the output of the logic gate, for compensating for voltage level losses when the output being in a high logic state,
wherein the logic block discharges the voltage that corresponds to the high logic state to ground, following logic operations that entail a low logic state, via an inherent current leakage path in the components implementing the logic block.

The logic gate may further comprise a pull-down block connected between the logic block and the output of the logic gate, for further discharging the voltage that corresponds to the high logic state to ground, following logic operations that entail a low logic state, in addition to discharging via the inherent current leakage path.

The restoration block may consist of:
a standard CMOS inverter;
a standard CMOS buffer;
a Schmitt trigger;
any combination thereof.

The pull-down block may be a diode.

The pull-down block may be implemented by:
a diode (e.g. a junction diode);
a transistor configured to operate as a diode;
a plurality of transistors configured to operate as a diode;
a combination of PMOS and NMOS transistors that acts as a diode.

The logic block may be a stack of connected transistors, implementing an AND, OR, NOR, or NAND gate, or a parallel connection of transistors implementing an AND, OR, NOR, or NAND gate, or a combination thereof including AND-OR-Invert, OR-AND-invert and the like.

The logic gate may further comprise:
a) a voltage source being connected to the source or drain of a first transistor of the stack; and
b) multiple voltage sources being connected as inputs to the gates of the transistors of the stack.

The logic block may comprise one or more CMOS circuits in combination with a stack of transistors.

The logic gate may operate in combination with similar logic gates, thereby forming a logic circuit.

The logic gate may be implemented as an integrated circuit in combination with CMOS gates.

The body of one or more transistors implementing the logic block may be connected to ground.

Multiple threshold voltages may be applied to transistors implementing each block.

Multiple power supply voltages may be used.

The supply voltage may be applied to the drain or source of at least one transistor implementing the logic block, or to the gate of at least one transistor implementing the logic block.

The logic gate may implement a multiple input AND, OR, NAND, and NOR gate with no load and no PMOS transistors.

The parasitic leakage current at the source of one or more transistors in the logic block may serve as a pull-down circuitry.

The logic gate may further comprise a feedback path from the input or the output of the restoration block, to control the operation of the pull-down circuit.

The logic gate may further comprise a circuit for sharing the same pull-down diode circuit and/or a signal restoring CMOS buffer between several stacked-NMOS gates, or NMOS gates connected in parallel, or a combination thereof.

The logic gate may further comprise several stacked-PMOS gates, or PMOS gates connected in parallel, or a combination thereof.

The logic gate may further comprise several stacked-NMOS and stacked-PMOS gates, or NMOS gates connected in parallel, PMOS gates connected in parallel, or a combination thereof.

### BRIEF DESCRIPTION OF THE DRAWINGS

The above and other characteristics and advantages of the invention will be better understood through the following illustrative and non-limitative detailed description of preferred embodiments thereof, with reference to the appended drawings, wherein:

FIG. 1 is a simplified block diagram of a generalized logic gate, implemented according to an embodiment of the present invention;

FIG. 2 (prior art) shows an example of the implementation of a circuit diagram of a three-input CMOS AND gate;

FIG. 3 is a circuit diagram of a three-input AND gate, implemented according to an embodiment of the present invention;

FIG. 4 (prior art) shows an example of the implementation of a CMOS 3-3AND-OR circuit;

FIG. 5 is a circuit diagram of a 3-3AND-OR circuit for sharing the same pull-down diode circuit and a signal restoring CMOS buffer, implemented according to an embodiment of the present invention;

FIG. 6 is a circuit diagram of an embodiment of a pull-down circuit comprising of NMOS transistor with feedback from the gate's output, implemented according to an embodiment of the present invention;

FIG. 7 presents several embodiments of pull-down circuits, implemented according to an embodiment of the present invention;

FIG. 8 is a circuit diagram of a high Fan-in, ten inputs AND gate, implemented according to an embodiment of the present invention;

FIG. 9a is a plot of a SPICE simulation of the rise time of ten inputs AND gate, implemented according to an embodiment of the present invention; and

FIG. 9b is a plot of a SPICE simulation of the fall time of ten inputs AND gate, implemented according to an embodiment of the present invention.

### DETAILED DESCRIPTION OF THE PRESENT INVENTION

The present invention relates to a single-type transistor (or a combination of different types) topology of static logic gates that incorporates either parasitic or pre-designed current leakage for pull-down as an inherent part of the logic operation and operands in digital logic circuits and in particular to its implementation in the design of combinatorial and asynchronous logic circuits.

The disclosed embodiments present static logic gates with no load and no complementary pull-down network in, but not limited to, a stack topology. A parasitic or pre-designed current leakage is used as a pull-down circuitry. Neither transistor source nor drain is connected to any of the data inputs. The presented logic gates provide cells that allow the general design of integrated circuits.

In an embodiment, the logic gate is implemented as an integrated circuit in combination with CMOS gates.

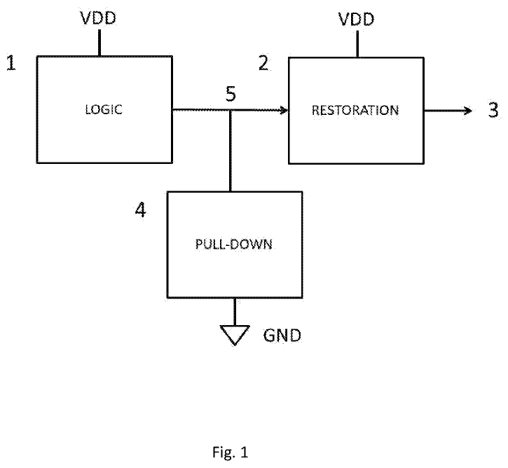

FIG. 1 is a simplified block diagram of a generalized logic gate, implemented according to an embodiment of the present invention. Logic block 1 consists of multiple data inputs that are connected to a plurality of gates of single-type transistors that compute a logic function. The logic block is a stack of connected transistors that implements an AND, OR, NOR, NAND gate, or a parallel connection of transistors implementing an AND gate, or a combination thereof. The logic block may further include a voltage source that is connected to the source or drain of a first transistor of the stack and multiple voltage sources being connected as inputs to the gates of the transistors of the stack.

Neither transistor's source nor drain is connected to any of the data inputs. A driving voltage VDD provides the supply voltage to the logic block. In one aspect, the supply voltage is applied to the drain or source of at least one transistor implementing the logic block or to the gate of at least one transistor implementing the logic block.

In some implementations, an interconnect line 5 connects the output of the logic block 1 to an input of restoration block 2 that acts to output logic “1” and “0” voltages at the output 3. Restoration block 2 consists of a restoration circuit for compensating for voltage level losses when the output is in a high logic state. The logic block discharges the voltage that corresponds to the high logic state to ground, following logic operations that entail a low logic state, via an inherent current leakage path in the components implementing the logic block. In some embodiments of the present invention restoration block 2 could be a standard CMOS inverter, a standard CMOS buffer, a Schmitt trigger, and the like, or any combination thereof.

A pull-down block 4 discharges the interconnect line 5 to the ground when the output of logic block 1 is at a voltage that corresponds “0” logic. A minute fraction of the output current of logic block 1 is lost to the ground via pull-down block 4 when the output of logic block 1 is at a voltage that corresponds “1” logic. The pull-down block further discharges the voltage that corresponds to the high logic state to ground, following logic operations that entail a low logic state, in addition to discharging via the inherent current leakage path.

The pull-down block may be implemented by a diode (such as a junction diode), a transistor configured to operate as a diode, a plurality of transistors configured to operate as a diode, or a combination of PMOS and NMOS transistors that acts as a diode.

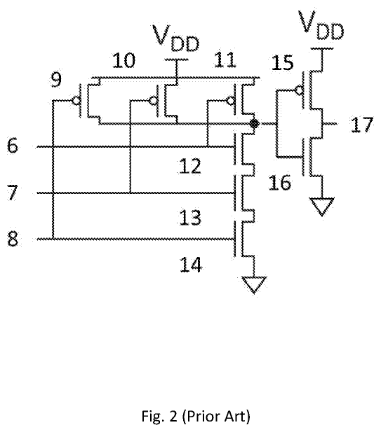

FIG. 2 (prior art) shows an example of the implementation of a circuit diagram of a three-input CMOS AND gate. Three inputs 6, 7, 8 are depicted. The three parallel-connected PMOS transistors 9, 10, 11 are connected to VDD and act as a load. The three serially connected NMOS transistors 12, 13, 14 are connected to the ground and serve as a pull-down network. The gate's output is 17.

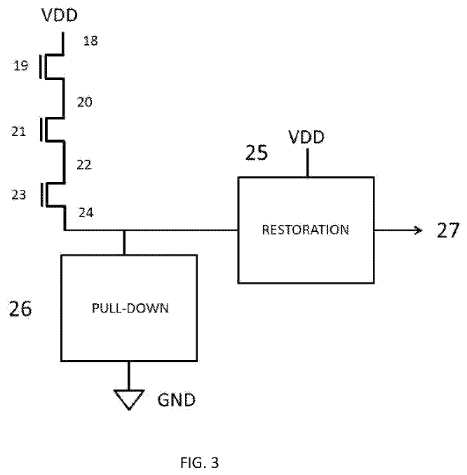

FIG. 3 is a circuit diagram of a three-input AND gate, implemented according to an embodiment of the present invention. In accordance with one embodiment of the present invention, a 3-input AND gate circuit consists of three serially connected NMOS transistors with no load and no PMOS transistors, a restoration circuit 25, and a pull-down circuit 26. When all inputs 19, 21, 23 are high, the supply voltage VDD is transferred to node 24 with a threshold voltage drop V_{T}.

$$V \approx V D D - {V}_{T} \qquad ( 1 )$$

In some embodiments of the present invention, the three stacked NMOS transistors topology 19, 21, 23 alone with a pull-down circuitry 26 will suffice for performing a three-input AND logic operation. Therefore, the proposed topology reduces the number of transistors that are required to realize a three-input AND gate, thereby improving the packing density. A lack of PMOS load transistors reduces the input impedance and thereby, improves the switching speed. It also allows for high Fan-in that is not reachable by CMOS logic. Namely, multiple-input gates of more than five inputs are feasible simply by extending the stack length with no requirement for multi-stage or sequential topology. Furthermore, this topology of stacked NMOS transistors improves static power dissipation due to reduced subthreshold leakage current because of the “stacking-effect” as reported by Nikhil Saxena and Sonal Soni, “Leakage current reduction in CMOS circuits using stacking effect”, International Journal of Application or Innovation in Engineering & Management, Vol. 2, Issue 11, pp. 213-216, 2013, by Ankita Nagar, and Vidhu Parmar, “Implementation of Transistor Stacking Technique in Combinational Circuits”, IOSR Journal of VLSI and Signal Processing, Vol. 4, Issue 5, pp. 1-5, 2014, and others.

In some embodiments of the present invention, the logic gate may further comprise several stacked-PMOS gates, or PMOS gates connected in parallel, or a combination thereof.

In some embodiments of the present invention, the logic gate may further comprise several stacked-NMOS and stacked-PMOS gates, or NMOS gates connected in parallel, PMOS gates connected in parallel, or a combination thereof.

In some embodiments of the present invention, restoration circuit 25 is adapted to restore the voltage V at 24 to be equal to VDD at the output 27. Restoration circuit 25 could be a standard CMOS inverter, a standard CMOS buffer, and the like. In some embodiments of the present invention, the parasitic leakage current at the source of transistor 23 (i.e. junction 24) could serve as a pull-down circuitry. In some other embodiments of the present invention, a pull-down circuit 26 could be a pre-designed device or circuit such as a single diode or plurality of diodes, a single transistor configured to act as a diode, a plurality of transistors that are connected such as to act as a diode, or any other circuitry that acts as a diode. Furthermore, a feedback path from the output 27 to the pull-down circuit 26 or from any other part of the circuit could be implemented to control the operation of pull-down circuit 26. The logic gate can implement a multiple-input AND gate with no load and no PMOS transistors. The parasitic leakage current at the source of one or more transistors in the logic block serves as a pull-down circuitry independently, or in parallel to the pull-down block 26.

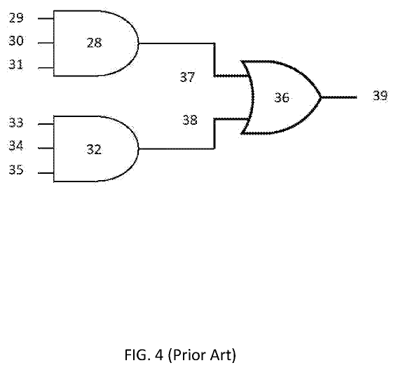

FIG. 4 (prior art) shows an example of the implementation of a CMOS 3-3AND-OR circuit with two three-input CMOS AND gates 28 and 32, whose outputs are connected to a two-input CMOS OR gate 36. This small circuit performs an OR logic function between two inputs 28 and 32, out of the three-input AND gates. The minimal transistor count of a CMOS 3-3AND-OR circuit is eleven NMOS transistors and eleven PMOS transistors. The area of a PMOS transistor is roughly three times the area of an NMOS transistor. Hence, reducing the number of PMOS transistors is an effective way to increase packing density.

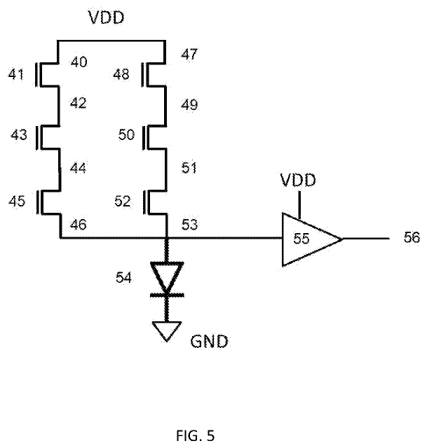

FIG. 5 is a circuit diagram of a 3-3AND-OR circuit for sharing the same pull-down diode circuit and a signal restoring CMOS buffer, implemented according to an embodiment of the present invention. This realization of a 3-3AND-OR circuit comprises no PMOS load and two three-stacked-NMOS AND gates 41, 43, 45 and 48, 50, 52 that are connected in parallel to a standard CMOS buffer 55 that is used for restoring V at 46 to be VDD. The two three-stacked-NMOS AND gates share the same pull-down circuitry, thereby saving silicon area. The presented topology does not require a two-input CMOS OR gate and therefore, delivers further area saving. FIG. 5 depicts one of the embodiments of a pre-designed pull-down circuit using a single diode. In order for the current loss to be minute when either of the AND gates activates the series resistance of the diode—when activated (forward resistance)—should be roughly 1 MΩ. The transistor count of the present invention 3-3AND-OR circuit is eight NMOS transistors and two PMOS transistors. In some embodiments, a PMOS transistor configured as a diode could be used as a pull-down device. In such an embodiment, the transistors count would be eight NMOS transistors and three PMOS transistors. Therefore, the transistor topology that is depicted in FIG. 5 results in significant area saving, i.e. increased packing density, as well as reduced static power dissipation. Further area saving is achieved because of reduced wiring due to a smaller number of transistors.

Multiple threshold voltages are also incorporated in the gates presented in the present invention. Using Low Threshold Voltage (LVT) transistors for the logic block minimizes the threshold voltage drop of equation (1) while using Standard Threshold Voltage (SVT) maintains the performance of the restoration block. In one embodiment, the threshold voltage of transistors 41, 43, 45 and transistors 48, 50, and 52 would be LVT (e.g. 100 mV for a typical 16 nm FinFET technology), while the threshold voltage of the buffer 55 transistors would be SVT (e.g. 250 mV for 16 nm FinFET technology) as well as high threshold voltage (HVT) such as 300 mV.

In some embodiments, multiple driving voltages are used to tune the switching performance of the first inverter of the buffer 55. Accordingly, a power supply voltage VDD1 that is different than VDD is connected to the first inverter of the buffer 55. In some other embodiments, the channel width of the inverter transistors would be modified to a

$$\frac{{W}_{P}}{{W}_{N}}$$

ratio, rather than the commonly used

$$\frac{{W}_{P}}{{W}_{N}} = 3 ,$$

so as to shift the commutation voltage of the first inverter of buffer 55.

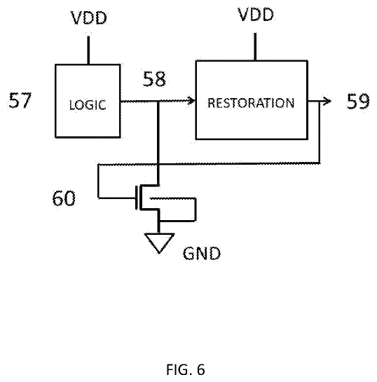

FIG. 6 depicts an embodiment of a feedback path from the gate's output 59 to a pull-down circuit comprising of NMOS transistor 60.

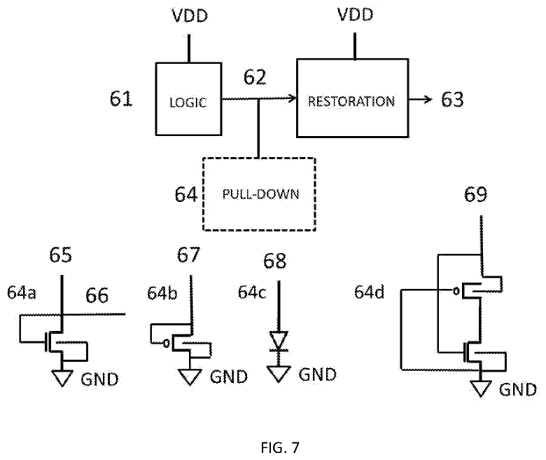

FIG. 7 presents four embodiments of pull-down circuits 64a, 64b, 64c, 64d. NMOS transistor 64a is connected to feedback 66, where node 65 is connected to 62; PMOS transistor 64b is configured as a diode where node 67 is connected to 62. A diode 64c where node 68 is connected to 62; The diode can be a PN or NP diode or a complex structure thereof, such as PNP, PNPN, etc. Embodiment 64d presents a circuit comprising a combination of PMOS and NMOS transistors that acts as a diode where node 69 is connected to 62. Additional circuits can be constructed by a person who is skilled in the art, to which the invention pertains.

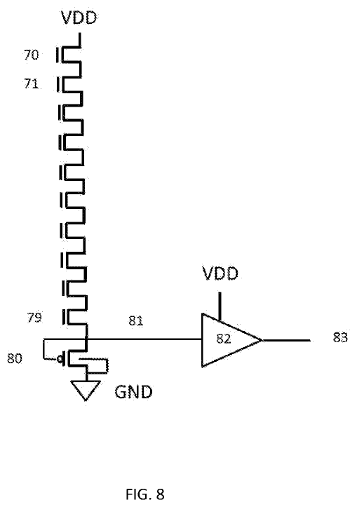

FIG. 8 is a circuit diagram of a high Fan-in, ten inputs AND gate, implemented according to an embodiment of the present invention. The circuit of FIG. 8 depicts an embodiment of a high Fan-in, ten-inputs, AND gate that exceeds beyond existing design capability of CMOS logic. The circuit consists of a stack of ten NMOS transistors 70-79, an interconnect 81 to a standard CMOS buffer 82 for restoration, gate output 83 and a PMOS transistor 80 configured as a diode that acts as a pull-down circuit.

Conventional CMOS VLSI is limited by the input impedance of the logic gate that adversely affects its frequency response. High Fan-in allows reduced circuit depth, due to the reduced number of sequential logic stages. This saves silicon area and moreover, the shallower a circuit is, the faster it is.

Furthermore, the stack topology of the high FAN-in gate that is depicted in FIG. 8 significantly inhibits subthreshold leakage, thereby obtaining reduced static power dissipation.

### Performance

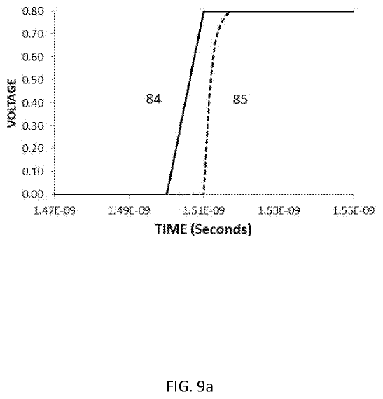

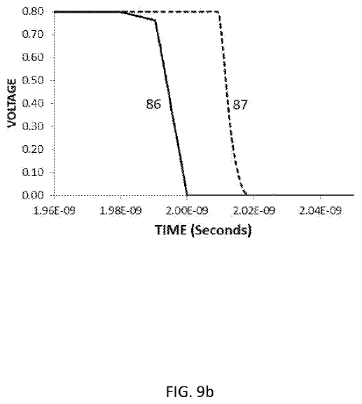

The gate's SPICE simulation results of the rise and fall times of the circuit of FIG. 8 are presented in FIGS. 9a and 9b, respectively. The simulation was carried out for a 16 nm CMOS FinFET technology running at a 1 GHz clock rate of fifty percent duty cycle where all ten transistors 70-79 are switched on and off simultaneously. Vdd is 0.8V.

FIG. 9a is a plot of the output voltage versus clock time of a SPICE simulation of the rise time of a ten-inputs AND gate, implemented according to an embodiment of the present invention. The leading edge of the clock pulse 84 is followed by a rise of the gate's output voltage 85. The performance is on par with state-of-the-art CMOS technology. The solid line is a clock leading-edge, the dotted line is the gate's response.

FIG. 9b is a plot of the output voltage versus clock time of a SPICE simulation of the fall time of ten inputs AND gate, implemented according to an embodiment of the present invention. The trailing edge of the clock pulse 86 is followed by a fall of the gate's output voltage 87. The performance is on a par with state-of-the-art CMOS logic technology. The solid line is a clock trailing edge, the dotted line is the gate's response.

FIGS. 9a and 9b show that the output voltage of the ten-inputs AND gate is maintained in a full swing.

### Robustness Considerations

One of the points of suitable behavior of the proposed logic technique is that the voltage drop V=VDD−V_{T} is minimal and that the pull-down voltage is close to ground voltage. In this section, consideration of fabrication process variability, power supply voltage tolerance and temperature variation on restoration block 2 is presented.

In an embodiment where restoration block 2 is comprised of a CMOS inverter or buffer the commutation voltage Vₘ of a voltage-transfer-curve (VTC) of a planar conventional CMOS inverter where

$$\frac{{β}_{N}}{{β}_{P}} = 1$$

and V_{T,N}≅|V_{T,P}| is:

$${V}_{m} = \frac{V D D + \sqrt{\frac{{β}_{N}}{{β}_{p}}} {V}_{T , N} - \vert {V}_{T , P} \vert}{1 + \sqrt{\frac{{β}_{N}}{{β}_{P}}}} ≅ \frac{V D D}{2} \qquad ( 2 )$$

For conventional CMOS logic, the commutation voltage Vₘ of a VTC of a logic gate depends on the input pattern since a CMOS gate is comprised of NMOS and PMOS transistors; therefore CMOS logic requires a relatively large noise margin. In the present invention, only a single type of transistor (i.e. vs. a CMOS pair) or their combination is used for realizing logic functions. This makes the voltage Vm stable, as well as independent of the input pattern, and allows for suitable operation under a tighter noise margin.

For supply voltage tolerance ΔVDD, conventional design of

$$\frac{{β}_{N}}{{β}_{P}} ≅ 1$$

and fabrication process threshold voltage variability σ_{VT}; the worst-case variation of Vm determines the required noise margin and is:

$$Δ V m ≅ \frac{Δ V D D}{2} + 0.7 {σ}_{V T} \qquad ( 3 )$$

Fabrication process variability also affects

$$\frac{{β}_{N}}{{β}_{P}}$$

but to a lesser extent that does not significantly alters ΔVm. Therefore, a suitable behavior of the proposed logic technique requires that V>Vm+ΔVm when the present invention logic block 1 switches to logic state “1”. When the present invention logic block 1 switches to logic state “0”, pull-down block 4 is required to discharge connection 5 to a voltage V<Vm−ΔVm.

High temperature reduces the threshold voltage of MOSFETs; advanced technology nodes using FinFETs present lower threshold voltage variations than planar transistors since the former's channel is either un-doped or slightly doped which reduces the impact of random doping fluctuations. Moreover, the temperature-dependent threshold voltage shift of NMOS is roughly equivalent to that of PMOS such that their difference in equation (2) roughly cancels out. Therefore the temperature stability of the commutation voltage Vₘ of restoration block 2 comprising of CMOS inverter or buffer is negligible with respect to the other factors that were analyzed.

In one embodiment, a supply voltage different than VDD of logic block 1 is applied to restoration block 2 to tune its commutation voltage Vₘ.

In another embodiment, single or multiple threshold voltages different than that of logic block's 1 transistors are used in restoration block 2 and/or pull-down block 3.

In a further embodiment, channel widths different than that of logic block's 1 transistors are used in restoration block 2 and/or pull-down block 3.

### Power Dissipation Considerations

When logic block 1 switches to a logic state “1”, a fraction of the current that charges connection 5 to voltage V leaks to ground via pull-down block 4. One of the points for accepted performance of the proposed logic technique is that this leakage current is tolerable and that the overall power dissipation is not adversely affected. The impact of this leakage current is tolerable when it is a minute fraction of the total current that charges connection 5.

In one embodiment, a design of pull-down block 4 is made to meet a specific leakage current requirement. Such design is commonly understood by a person skilled in the art to which the invention pertains.

In an embodiment, sparse use of the present invention logic gates is made in a circuit such as to meet a required power dissipation limit.

In an embodiment of the present invention, a switching aware use of the logic gates is made in a circuit, so as to meet a required power dissipation limit.

In an embodiment of the present invention, a Fan-in aware use of the logic gates is made in a circuit, so as to meet a required power dissipation limit.

### Advanced Logic Functions

In order to perform advanced logic operations, any logic function may be reduced to a combination of AND, OR and NOT gates using suitable logic reduction and mapping techniques such as karnaugh map, Quine-McCluskey method and the like. Construction of complex logic functions or high Fan-in gates of three inputs or more by conventional CMOS logic requires sequential design of staging multiple AND, OR and NOT gates that consume a large area and reduce the speed of a circuit.

Returning back to FIG. 8, the proposed logic technique allows for designing circuits of fewer stages comprising a smaller number of AND, OR and NOT gates thereby being faster as well as consuming less area than conventional CMOS logic.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub-combination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

1. A logic gate circuit, comprising:
a) a logic block for performing logic operations between inputs of said logic block; and
b) a restoration block, connected between the output of said logic block and the output of said logic gate, for compensating for voltage level losses when said output being in a high logic state,
wherein said logic block discharges the voltage that corresponds to said high logic state to ground, following logic operations that entail a low logic state, via an inherent current leakage path in the components implementing said logic block.

2. A logic gate according to claim 1, further comprising a pull-down block connected between said logic block and the output of said logic gate, for further discharging the voltage that corresponds to said high logic state to ground, following logic operations that entail a low logic state, in addition to discharging via the inherent current leakage path.

3. A logic gate according to claim 1, in which the restoration block consists of:
a standard CMOS inverter;
a standard CMOS buffer;
a combination thereof.

4. A logic gate according to claim 1, in which the pull-down block is a diode.

5. A logic gate according to claim 1, in which the pull-down block is implemented by:
a diode (e.g. a junction diode);
a transistor configured to operate as a diode;
a plurality of transistors configured to operate as a diode;
a combination of PMOS and NMOS transistors that acts as a diode.

6. A logic gate according to claim 1, in which the logic block is a stack of connected transistors, implementing an AND, OR, NOR, NAND gate, or a parallel connection of transistors implementing an AND gate, or a combination thereof.

7. A logic gate according to claim 6, further comprising:
a) a voltage source being connected to the source or drain of a first transistor of the stack; and
b) multiple voltage sources being connected as inputs to the gates of the transistors of said stack.

8. A logic gate according to claim 6, in which the logic block comprises one or more CMOS circuits in combination with a stack of transistors.

9. A logic gate according to claim 1, operating in combination with similar logic gates, thereby forming a logic circuit.

10. A logic gate according to claim 1, implemented as an integrated circuit in combination with CMOS gates.

11. A logic gate according to claim 1, in which the body of one or more transistors implementing the logic block is connected to the ground.

12. A logic gate according to claim 1, in which multiple threshold voltages are applied to transistors implementing each block.

13. A logic gate according to claim 1, in which multiple power supply voltages are used.

14. A logic gate according to claim 1, in which the supply voltage is applied to the drain or source of at least one transistor implementing the logic block.

15. A logic gate according to claim 7, in which the supply voltage is applied to the gate of at least one transistor implementing the logic block.

16. A logic gate according to claim 1, implementing a multiple-input AND gate with no load and no PMOS transistors.

17. A logic gate according to claim 1, in which the parasitic leakage current at the source of one or more transistors in the logic block serves as a pull-down circuitry.

18. A logic gate according to claim 1, further comprising a feedback path from the input or the output of the restoration block, to control the operation of said pull-down circuit.

19. A logic gate according to claim 1, further comprising a circuit for sharing the same pull-down diode circuit and/or a signal restoring CMOS buffer between several stacked-NMOS gates, or NMOS gates connected in parallel, or a combination thereof.

20. A logic gate according to claim 1, further comprising several stacked-PMOS gates, or PMOS gates connected in parallel, or a combination thereof.

21. A logic gate according to claim 1, further comprising several stacked-NMOS and stacked-PMOS gates, or NMOS gates connected in parallel, PMOS gates connected in parallel, or a combination thereof.
